(19) United States
(12) Patent Application Publication
(10) Pub. No.: US 2011/0291263 A1
(43) Pub. Date: Dec. 1, 2011

(54) IC HAVING DIELECTRIC POLYMERIC COATED PROTRUDING FEATURES HAVING WET ETCHED EXPOSED TIPS

(75) Inventor: Jeffrey A. West, Dallas, TX (US)

(73) Assignee: TEXAS INSTRUMENTS INCORPORATED, Dallas, TX (US)

(21) Appl. No.: 12/790,441

(22) Filed: May 28, 2010

(51) Int. Cl. H01L 23/28; H01L 21/56

(52) U.S. Cl. 257/737; 438/780; 257/E21.502; 257/E23.116

(57) ABSTRACT

A method of fabricating IC die includes providing a substrate having a topside semiconductor surface including active circuitry and a bottomside surface. The IC die includes at least one protruding feature coupled to the active circuitry that protrudes from the bottomside surface or the topside semiconductor surface. The topside semiconductor surface and/or bottomside surface and the protruding feature are coated with a dielectric polymer. A portion of the dielectric polymer is removed from the protruding feature using a solvent to expose a tip portion of the protruding feature for electrical connection thereto. With a solvent that does not corrode or oxidize the exposed protruding feature tips, the need for a conventional subsequent chemical exposure to remove corrosion or oxidation is avoided.

### FIELD

Disclosed embodiments relate to integrated circuits (IC) devices having polymer coated protruding bonding features with exposed tips and packaged ICs therefrom.

### BACKGROUND

ICs include a plurality of bonding features on their outer surface (topside and/or bottomside surface) for bonding to a substrate, such as another die, a wafer, or a package substrate (e.g., PCB). The bonding features can generally comprise bonding structures such as bond pads, studs, through silicon vias which are referred to herein more generally as through substrate vias (TSVs), or pillars. TSVs provide a vertical connection from the topside (active circuit side) of the IC die (e.g., coupled to one of the metal interconnect layers) to the bottomside surface of the IC die. The TSVs tips on the bottomside surface of the IC die can be protruding, flush or recessed relative to the surrounding bottomside surface, which is commonly a semiconductor surface (e.g., Si).

In the case of protruding bonding features, such as pillars or protruding TSV tips, a dielectric polymer passivation layer can be used to electrically isolate the metals comprising the subsequently formed bond at the protruding features (e.g., Sn, Ni, Pd, Cu) from the surrounding semiconductor (e.g. Si). In the case of a polymer passivation layer, the conventional method for exposing the tips of the embedded protruding features is to blanket etch-back the polymer in a CxFy/oxygen containing plasma environment, to reveal the tips of the embedded protruding feature, leaving some dielectric polymer behind on the surface of the IC and adjacent to a portion of the protruding feature (e.g., first several μms of the protruding feature).

However, as known in the art, fluorinated plasma etch processes can lead to corrosion of exposed metal and oxygenated plasma processes can result in oxidation of the protruding features tips when the tips comprise an oxidizable material, such as metals including copper, that during the plasma treatment forms a metal oxide dielectric (e.g., copper oxide) on its surface. A subsequent wet etch step, such as acetic acid in the case of copper oxide, is generally used to remove the copper oxide from the tip of the protruding feature to allow electrical connection thereto.

### SUMMARY

Disclosed embodiments include ICs having dielectric polymeric coated protruding bonding features having wet etched exposed tips and related methods for fabricating such ICs. Disclosed embodiments solve the problem of corroded/oxidized protruding feature tips due to conventional CₓF_{y}/O₂ plasma etching of the tips by instead using a wet polymer etch that is typically a solvent or developer. Using an appropriate solvent or developer (hereafter referred to as a solvent), corrosion or oxidation resulting from solvent exposure to form the exposed tips is avoided which removes the need for a subsequent wet chemical exposure, thus providing a lower cost and more efficient solution for forming dielectric polymeric coated protruding features having exposed tips.

A method of fabricating an IC die includes providing a substrate having a topside semiconductor surface including active circuitry and a bottomside surface. The IC die comprises at least one protruding feature coupled to the active circuitry that protrudes from the bottomside surface or the topside semiconductor surface. The protruding feature is coated with a dielectric polymer. A portion of the dielectric polymer is removed from the protruding feature using a solvent to expose a tip portion of the protruding feature for electrical connection thereto. The removal process is capable of removing the dielectric polymer in a controlled manner. Using a solvent that does not corrode or oxidize the exposed protruding feature tips, the need for a subsequent chemical etch required by conventional processing to remove the corrosion or oxidation formed on the tip is avoided.

### BRIEF DESCRIPTION OF THE DRAWINGS

FIG. 1 is a flow chart that shows steps in an exemplary method for forming ICs having dielectric polymeric coated protruding features having wet etched exposed tips, according to an embodiment of the invention.

FIGS. 2A-C are a series of cross sectional views showing steps in an exemplary process to form an IC die having dielectric polymeric coated protruding features having wet etched exposed tips, where the protruding features comprise TSVs that protrude from the bottomside surface of the IC die, according to a disclosed embodiment.

FIG. 3 is a cross sectional depiction of an IC die having dielectric polymeric coated protruding features having wet etched exposed tips that includes TSVs comprising an electrically conductive portion within an outer dielectric liner, wherein the protruding features comprise pillars that protrude from the bottomside surface that is coupled to the TSV by a redirect layer (RDL) that is over the TSVs, according to an embodiment of the invention.

FIG. 4 is a cross sectional depiction of an IC die having dielectric polymeric coated protruding features having wet etched exposed tips that includes protruding features comprising pillars that protrude from the topside semiconductor surface, according to an embodiment of the invention.

### DETAILED DESCRIPTION

Disclosed embodiments in this Disclosure are described with reference to the attached figures, wherein like reference numerals are used throughout the figures to designate similar or equivalent elements. The figures are not drawn to scale and they are provided merely to illustrate the disclosed embodiments. Several aspects are described below with reference to example applications for illustration. It should be understood that numerous specific details, relationships, and methods are set forth to provide a full understanding of the disclosed embodiments. One having ordinary skill in the relevant art, however, will readily recognize that the subject matter disclosed herein can be practiced without one or more of the specific details or with other methods. In other instances, well-known structures or operations are not shown in detail to avoid obscuring structures or operations that are not well-known. This Disclosure is not limited by the illustrated ordering of acts or events, as some acts may occur in different orders and/or concurrently with other acts or events. Furthermore, not all illustrated acts or events are required to implement a methodology in accordance with this Disclosure.

Notwithstanding that the numerical ranges and parameters setting forth the broad scope of this Disclosure are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

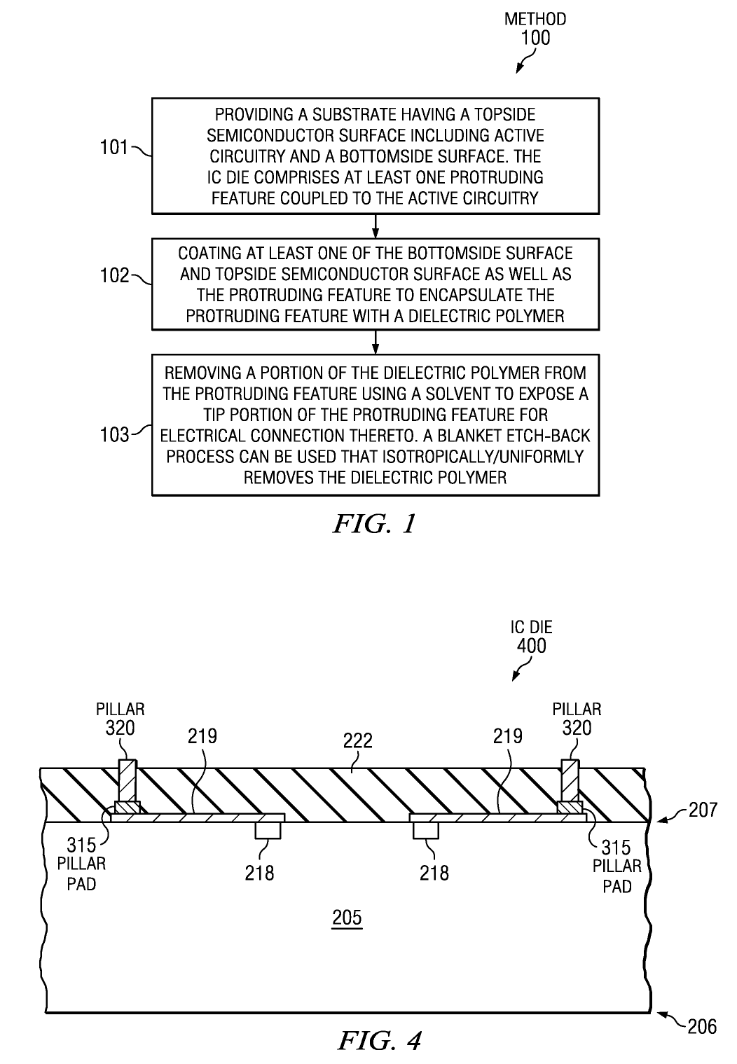

FIG. 1 is a flow chart that shows steps in an exemplary method for forming IC die having dielectric polymeric coated protruding features having wet etched exposed tips, according to an embodiment of the invention. Step 101 comprises providing a substrate having a topside semiconductor surface including active circuitry and a bottomside surface. The IC die comprises at least one protruding feature coupled to the active circuitry. The providing step can comprise providing a substrate wafer having a plurality of IC die. In another embodiment, the providing step can comprise providing a plurality of IC die embedded into or onto a carrier wafer (e.g., a glass or silicon carrier wafer).

The protruding feature protrudes from the bottomside surface or topside semiconductor surface, typically a distance of 2 to 50 μms. The protruding features can comprise one or more of several different protruding feature types, including TSVs, pillars and studs. The length of the protruding feature is generally 2-10 μm for TSVs, and 10-40 μm for pillars (e.g., copper pillars). The protruding features generally comprise an oxidizable metal or oxidizable metal alloy, such as comprising copper. In one embodiment, the protruding features comprise TSVs that protrude from the bottomside surface of the IC die. In this embodiment, no RDL is needed. In another embodiment, the protruding features comprise pillars that protrude from the bottomside surface of the IC die to an RDL over a TSV. In another embodiment, the protruding features comprise pillars protruding from the topside semiconductor surface of the IC die and the IC die does not include TSVs. These embodiments may be combined.

Step 102 comprises coating at least one of the bottomside surface and topside semiconductor surface as well as the protruding feature to encapsulate the protruding feature with a dielectric polymer. Coating can comprise a spin-on process. Other coating processes may also be used, such as lamination of a dry film. Exemplary dielectric polymers comprises poly-p-phenylenebenzobisoxazole (PBO) or one of the polyimides (PIs). Dielectric polymer on both sides of the IC die can help control warpage, particularly when the IC die are in thinned wafer form.

Step 103 comprises removing a portion of the dielectric polymer from the protruding feature using a solvent to expose a tip portion of the protruding feature for electrical connection thereto. A blanket etch-back process can be used that isotropically/uniformly removes the dielectric polymer. The solvent for PBO can be tetramethylammonium hydroxide (TMAH)-based. A solvent for PI can be cyclopentanone-based with 1-methoxy-2-propanol acetate (pgmea) for an etch stop. The removing step generally involves etching the dielectric polymer until the exposed tips protrude by a predetermined amount. In one particular embodiment, the TSV tip is 4 to 6 μm long and 1 to 3 μm of the dielectric polymer remains on the base of the TSV tip after step 103.

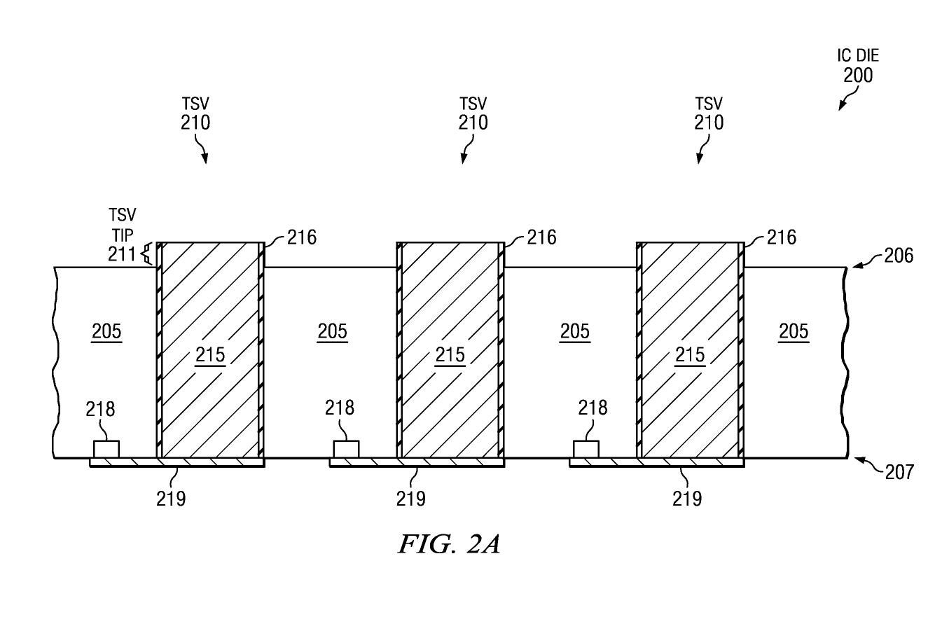

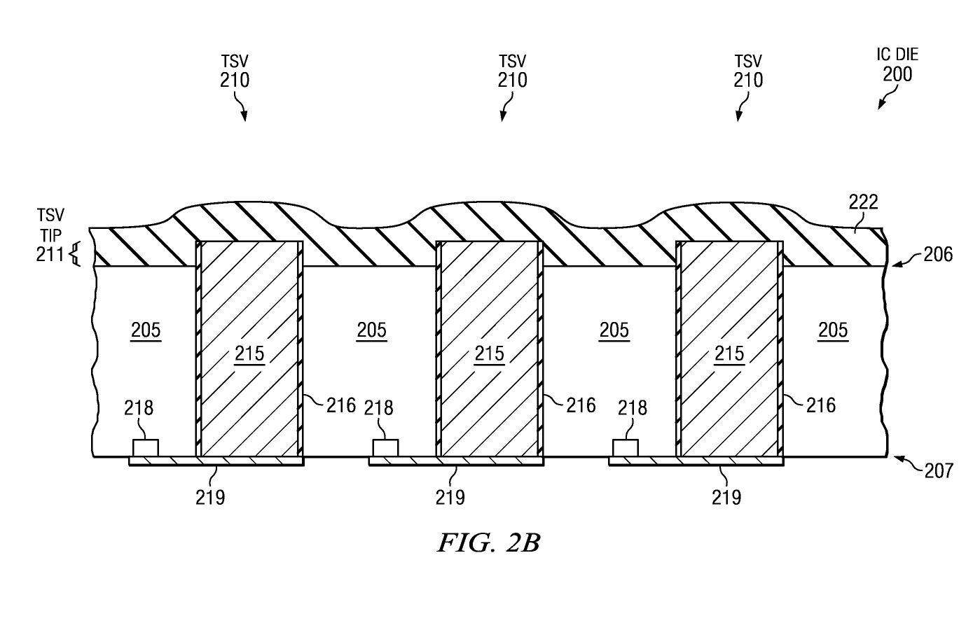

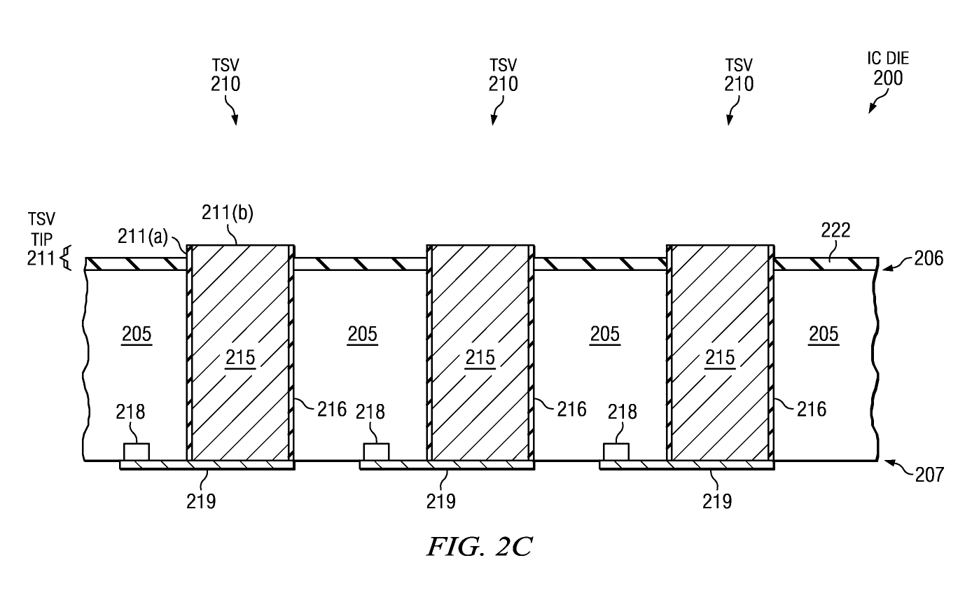

FIGS. 2A-C are a series of cross sectional views showing steps in an exemplary process to form an IC die 200 having dielectric polymeric coated protruding features having wet etched exposed tips, where the protruding features comprise TSVs that protrude from the bottomside surface of the IC die, according to a disclosed embodiment. IC die 200 comprises a substrate 205 having a topside semiconductor surface 207 and a bottomside surface 206, where the TSVs 210 include TSV tips 211 that protrude from the bottomside surface 206 of a substrate 205. Substrate 205 can include a variety of semiconductors such as GaAs, Group III-N semiconductors (e.g., GaN), and silicon, including certain compounds (alloys) of silicon, including but not limited to, silicon germanium (SiGe) and silicon carbide (SiC). Semiconductor on insulator (SOI), such as silicon on insulator, can also be used.

TSV 210 includes electrically conductive core portion 215 and an outer dielectric liner 216. Active circuitry 218 on the topside semiconductor surface 207 is shown coupled to TSV 210, such as by a metal interconnect layer 219 (e.g., M1, or M2, etc.). FIG. 2B is a cross section depiction showing IC die 200 after coating with a dielectric polymer 222, for example using a spin coating process as described above. Note that the thickness of dielectric polymer 222 over the TSV tips 211 is significantly less than the thickness of the dielectric polymer 222 over the other areas of bottomside surface 206. FIG. 2C is a cross section depiction showing IC die 200 after wet etching the dielectric polymer 222 so that exposed tip portions 211(a) of the dielectric polymer 222 on TSV tips 211 are exposed, and the dielectric polymer 222 remains on the remainder of the TSV tip 211 and on the bottomside surface 206 of the IC die 200.

The top surface 211(b) of the exposed tip portion 211(a) of the TSV tip 211 can be seen to be highly planar, where the top surface 211(b) of the exposed tip portion 211(a) of the TSV tip 211 including the top surfaces of electrically conductive portion 215 and outer dielectric liner 216 which are highly planar relative to one another. This may be contrasted to a TSV top surface that is exposed by conventional CₓF_{y}/O₂ plasma etching for integration schemes that include dielectric liner 216 since the electrically conductive portion 215 (e.g., copper) of the TSV top surface 211(b) can corrode/oxidize to form a metal comprising dielectric while the dielectric liner 216 is a material not subject to corrosion/oxidation. Accordingly, upon the metal comprising dielectric subsequently being removed (e.g., acetic acid for copper oxide), the height of electrically conductive portion 215 at the top surface 211(b) of the TSV tip 211 will be sunken about 1-5 nm relative to the height of outer dielectric liner 216 at the top surface 211(b).

Other distinctions between IC die processed using embodiments of the invention as compared to conventional plasma etch removal of the dielectric polymer include ashing generally significantly roughens the dielectric polymer surface, whereas the all wet removal processes disclosed herein produces a wet etched surface that is characteristically smooth. Yet another distinction generally is that the dielectric polymer surface using disclosed embodiments is free of measurable fluorine levels, whereas conventional CₓF_{y}/O₂ plasma etch removal of the dielectric polymer generally imparts trace levels of fluorine into surface of the dielectric polymer, estimated to be on the order of 1×10⁹ atoms/cm².

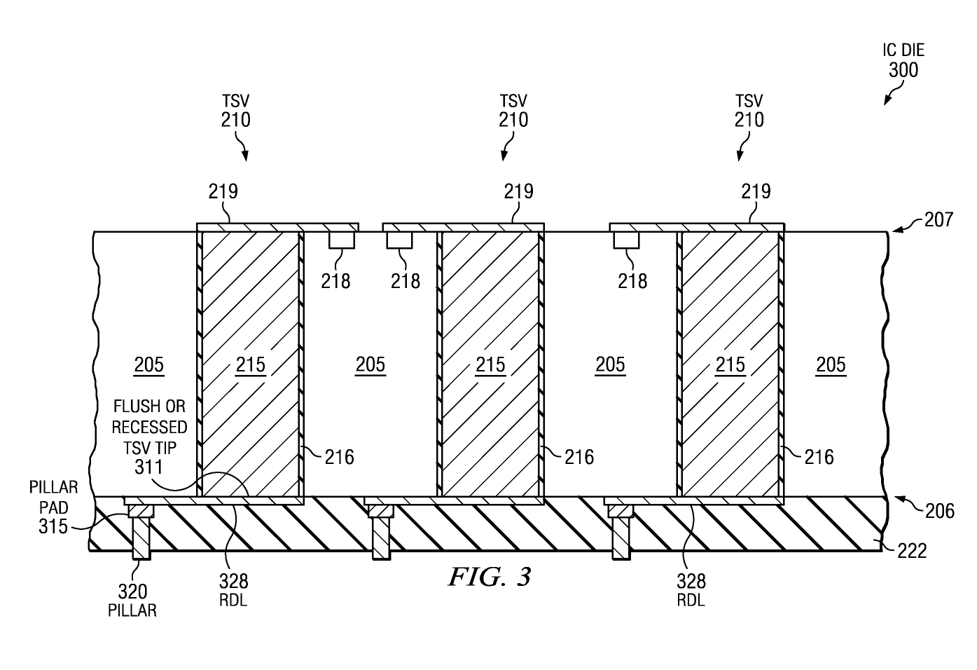

FIG. 3 is a cross sectional depiction of an IC die 300 having dielectric polymeric coated protruding features having wet etched exposed tips that includes TSVs comprising an electrically conductive portion within an outer dielectric liner, wherein the protruding features comprise pillars 320 on pillar pads 315 that protrude from the bottomside surface 206 of substrate 205 that is coupled to the TSVs 210 by a redirect layer (RDL) 328 to a flush or recessed tip 311 of TSVs 210, according to an embodiment of the invention. The pillars 320 can comprise copper pillars and do not generally have a dielectric liner 216 as does the TSVs 210.

Although not shown in FIG. 3, the TSVs 210 and pillars 320 are generally connected to different metal levels, which are interconnected by filled vias. For example, the TSV tip 311 may terminate at MET1 or MET2 of the topside interconnects, and Cu pillars 320 may attach to pillar pads 315 that are formed from the topmost metal (e.g., MET7 or MET8). Accordingly, the interconnection between TSVs 210 and pillars 320 can be more involved as compared to simplified interconnect arrangement comprising the RDL 328 shown in FIG. 3, since there can be a plurality (e.g., 3-8) of metal layers of BEOL interconnect between the TSV tip 311 and the pillar pads 315 and pillars 320.

FIG. 4 is a cross sectional depiction of an IC die 400 having dielectric polymeric coated protruding features having wet etched exposed tips that includes protruding features comprising pillars 320 that protrude from the topside semiconductor surface 207, according to an embodiment of the invention. As noted above, the pillars 320 can comprise copper and do not generally have a dielectric liner as do the TSVs 210 described above. Although not shown in FIG. 4, the pillar pad 315 and pillars 320 are generally connected to a top level conductor, such as MET8 for an 8 metal-level IC design.

The active circuitry formed on the topside semiconductor surface comprise circuit elements that generally include transistors, diodes, capacitors, and resistors, as well as signal lines and other electrical conductors that interconnect these various circuit elements. Disclosed embodiments can be integrated into a variety of process flows to form a variety of devices and related products. The semiconductor substrates may include various elements therein and/or layers thereon. These can include barrier layers, other dielectric layers, device structures, active elements and passive elements including source regions, drain regions, bit lines, bases, emitters, collectors, conductive lines, conductive vias, etc. Moreover, disclosed embodiments can be used in a variety of processes including bipolar, CMOS, BiCMOS and MEMS.

While various disclosed embodiments have been described above, it should be understood that they have been presented by way of example only, and not limitation. Numerous changes to the subject matter disclosed herein can be made in accordance with this Disclosure without departing from the spirit or scope of this Disclosure. In addition, while a particular feature may have been disclosed with respect to only one of several implementations, such feature may be combined with one or more other features of the other implementations as may be desired and advantageous for any given or particular application.

Thus, the breadth and scope of the subject matter provided in this Disclosure should not be limited by any of the above explicitly described embodiments. Rather, the scope of this Disclosure should be defined in accordance with the following claims and their equivalents.

The terminology used herein is for the purpose of describing particular embodiments only and is not intended to be limiting. As used herein, the singular forms “a,” “an,” and “the” are intended to include the plural forms as well, unless the context clearly indicates otherwise. Furthermore, to the extent that the terms “including,” “includes,” “having,” “has,” “with,” or variants thereof are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art to which embodiments of the invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

I claim:

1. A method of fabricating an integrated circuit (IC) die, comprising:
providing a substrate having a topside semiconductor surface including active circuitry and a bottomside surface, and at least one protruding feature coupled to said active circuitry, said protruding feature protruding from said bottomside surface or said topside semiconductor surface;
coating said bottomside surface or said topside semiconductor surface and said protruding feature (to encapsulate) with a dielectric polymer, and
removing a portion of said dielectric polymer from said protruding feature using a solvent to expose a tip portion of said protruding feature for electrical connection thereto.

2. The method of claim 1, wherein said IC die includes at least one through substrate via (TSV) comprising an electrically conductive portion within an outer dielectric liner.

3. The method of claim 2, wherein said protruding feature comprises a protruding TSV tip portion of said TSV that protrudes from said bottomside surface.

4. The method of claim 1, wherein said protruding feature comprises a metal pillar that protrudes from said topside semiconductor surface, wherein said metal is an oxidizable metal or oxidizable metal alloy.

5. The method of claim 4, wherein said oxidizable metal or oxidizable metal alloy comprises copper.

6. The method of claim 2, wherein said at least one protruding feature comprises a plurality of protruding features including a first protruding feature type comprising a protruding TSV tip portion of said TSV that protrudes from said bottomside surface and a second protruding feature type comprising a metal pillar that protrudes from said topside semiconductor surface.

7. The method of claim 1, wherein said providing comprises providing a substrate wafer having a plurality of said IC die.

8. The method of claim 1, wherein said providing comprises providing a plurality of said IC die embedded into or onto a carrier wafer.

9. The method of claim 1, wherein said coating comprises a spin-on dielectric process.

10. An integrated circuit (IC) die, comprising:
a substrate including a topside semiconductor surface including active circuitry and a bottomside surface;
at least one protruding feature coupled to said active circuitry that protrudes from said bottomside surface or said topside semiconductor surface, and
a dielectric polymer on said bottomside surface or said topside semiconductor surface and on a portion of said protruding feature, wherein a tip portion of said protruding feature is an exposed tip portion that does not include said dielectric polymer for electrical connection thereto, and
wherein a surface of said dielectric polymer is a wet-etched surface that is exclusive of fluorine.

11. The IC die of claim 10, wherein said protruding feature is a protruding through substrate via (TSV) tip portion of a TSV comprising an electrically conductive portion within an outer dielectric liner that protrudes from said bottomside surface.

12. The IC die of claim 11, wherein said electrically conductive portion and said outer dielectric liner both extend along an entire length of said protruding TSV tip portion, and
wherein a top surface of said exposed tip portion of said protruding TSV tip portion comprising said electrically conductive portion and said outer dielectric liner are planar relative to one another.

13. The IC die of claim 10, wherein said protruding feature comprises an oxidizable metal or oxidizable metal alloy.

14. The IC die of claim 13, wherein said oxidizable metal or oxidizable metal alloy comprises copper.

15. The IC die of claim 10, wherein said IC includes at least one through substrate via (TSV) comprising an electrically conductive portion within an outer dielectric liner, and
wherein said at least one protruding feature comprises a plurality of protruding features including a first protruding feature type comprising a protruding TSV tip portion of said TSV that protrudes from said bottomside surface and a second protruding feature type comprising a metal pillar that protrudes from said topside semiconductor surface.

16. The IC die of claim 10, wherein said dielectric polymer comprises poly-p-phenylenebenzobisoxazole (PBO) or a polyimide (PI).

17. The IC die of claim 10, wherein said IC includes at least one through substrate via (TSV) comprising an electrically conductive portion within an outer dielectric liner, and wherein said protruding feature comprises a pillar protruding from said bottomside surface that is coupled to said TSV by a redirect layer (RDL) that is over said TSV.

18. The IC die of claim 10, wherein said protruding feature comprises a pillar protruding from said topside semiconductor surface.
